(19) United States
(12) Patent Application Publication
(10) Pub. No.: US 2025/0130256 A1
(43) Pub. Date: Apr. 24, 2025

(54) APPARATUS FOR TESTING INTEGRATED CIRCUITS

(71) Applicant: MEDIATEK INC., Hsinchu City (TW)

(72) Inventors: Jing-Hui Zhuang, Hsinchu City (TW); Ying-Chou Shih, Hsinchu City (TW); Chang-Lin Wei, Hsinchu City (TW); Sheng-Wei Lei, Hsinchu City (TW); Chih-Yang Liu, Hsinchu City (TW); Jhih-Huei Chiu, Hsinchu City (TW); Yen-Hui Li, Hsinchu City (TW); Che-Sheng Lin, Hsinchu City (TW)

(73) Assignee: MEDIATEK INC., Hsinchu City (TW)

(21) Appl. No.: 18/906,148

(22) Filed: Oct. 3, 2024

Related U.S. Application Data
(60) Provisional application No. 63/591,478, filed on Oct. 19, 2023.

(51) Int. Cl. G01R 1/073; G01R 31/28

(52) U.S. Cl. CPC G01R 1/07342; G01R 31/2889

(57) ABSTRACT

A probe head includes an upper pin holder and a lower pin holder coupled to the upper pin holder. A pin arrangement space is defined between the upper pin holder and the lower pin holder. A conductive film is disposed between the upper pin holder and the lower pin holder. A plurality of probe pins penetrates through the upper pin holder, the conductor film and the lower pin holder, and extends outwardly from a bottom surface of the lower pin holder.

### CROSS REFERENCE TO RELATED APPLICATIONS

This application claims the benefit of U.S. Provisional Application No. 63/591,478, filed on Oct. 19, 2023. The content of the application is incorporated herein by reference.

### BACKGROUND

The present disclosure relates generally to the field of semiconductor technology, and more particularly to a probe card assembly adapted for testing integrated circuit devices formed on a semiconductor wafer.

As known in the art, semiconductor wafers are tested (or probed) before being diced and singulated into individual bare dice. The defective dice are marked and excluded from a subsequent packaging process after singulation. During wafer level testing, each die is tested by temporarily contacting power and signal input/output (I/O) connections, such as solder bumps, with probe pins mounted to a probe card assembly (or probe card).

Probe cards are typically used in the testing of integrated circuits on a wafer by providing an interface between the pads of a bare die formed on the wafer and test equipment. One conventional type of probe card uses a large number of probe pins extending outwardly from a bottom surface of a probe head to provide electrical contact with the pads on the die.

However, the prior art probe card assembly encounters various challenges, such as impendence matching issues, stub effects, and needle parasitic effects during testing.

### SUMMARY

It is one object of the invention to provide an improved probe card assembly for testing integrated circuits on a semiconductor wafer in order to solve the deficiencies or shortcomings of the prior art.

One aspect of the instant disclosure provides an apparatus for testing integrated circuits including a probe card circuit board; a probe head disposed under the probe card circuit board; and an interposing substrate disposed between the probe card circuit board and the probe head. The interposing substrate has a first interface coupled to the probe card circuit board and a second interface coupled to the probe head. The probe head includes an upper pin holder and a lower pin holder coupled to the upper pin holder. A pin arrangement space is defined between the upper pin holder and the lower pin holder. A conductive film is disposed between the upper pin holder and the lower pin holder. A plurality of probe pins penetrates through the upper pin holder, the conductor film and the lower pin holder, and extends outwardly from a bottom surface of the lower pin holder. According to some embodiments, the conductive film is disposed directly on an interior surface of the lower pin holder.

According to some embodiments, the conductive film is a metal film.

According to some embodiments, the plurality of probe pins includes cobra pins or MEMS pins.

According to some embodiments, the probe pins include a first pre-bent signal pin and a first pre-bent ground pin disposed in close proximity to the first pre-bent signal pin.

According to some embodiments, the probe head further includes a second pre-bent ground pin disposed in close proximity to the first pre-bent signal pin, wherein the first pre-bent signal pin is disposed between the first pre-bent ground pin and the second pre-bent ground pin, thereby forming a GSG pin configuration.

According to some embodiments, the probe head further includes at least one ground pin, wherein the at least one ground pin comprises a head terminal penetrating through the upper pin holder and a tip terminal landed on the conductive film to provide ground voltage to the conductive film during testing.

According to some embodiments, the tip terminal of the at least one ground pin is in direct contact with the conductive film.

According to some embodiments, a distance between the at least one ground pin and the first pre-bent signal pin is smaller than a distance between the first pre-bent ground pin and the first pre-bent signal pin.

According to some embodiments, the probe head further includes a second pre-bent signal pin disposed in close proximity to the first pre-bent signal pin, wherein the at least one ground pin is disposed between the first pre-bent signal pin and the second pre-bent signal pin.

According to some embodiments, the conductive film is part of a multi-layered substrate.

Another aspect of the instant disclosure provides a probe head of a probe card assembly for testing integrated circuits including an upper pin holder and a lower pin holder coupled to the upper pin holder. A pin arrangement space is defined between the upper pin holder and the lower pin holder. A conductive film is disposed between the upper pin holder and the lower pin holder. A plurality of probe pins penetrates through the upper pin holder, the conductor film and the lower pin holder, and extends outwardly from a bottom surface of the lower pin holder.

According to some embodiments, the conductive film is disposed directly on an interior surface of the lower pin holder.

According to some embodiments, the conductive film is a metal film.

According to some embodiments, the conductive film is in direct contact with the lower pin holder and the upper pin holder.

According to some embodiments, the plurality of probe pins includes cobra pins or MEMS pins.

According to some embodiments, the probe pins include a first pre-bent signal pin and a first pre-bent ground pin disposed in close proximity to the first pre-bent signal pin.

According to some embodiments, a second pre-bent ground pin is disposed in close proximity to the first pre-bent signal pin, wherein the first pre-bent signal pin is disposed between the first pre-bent ground pin and the second pre-bent ground pin, thereby forming a GSG pin configuration.

According to some embodiments, at least one ground pin is provided within the pin arrangement space. The at least one ground pin includes a head terminal penetrating through the upper pin holder and a tip terminal landed on the conductive film to provide ground voltage to the conductive film during testing.

According to some embodiments, the tip terminal of the at least one ground pin is in direct contact with the conductive film.

According to some embodiments, a distance between the at least one ground pin and the first pre-bent signal pin is smaller than a distance between the first pre-bent ground pin and the first pre-bent signal pin.

According to some embodiments, the probe head further comprises a second pre-bent signal pin disposed in close proximity to the first pre-bent signal pin, wherein the at least one ground pin is disposed between the first pre-bent signal pin and the second pre-bent signal pin.

According to some embodiments, the conductive film is part of a multi-layered substrate.

Still another aspect of the instant disclosure provides a probe head of a probe card assembly for testing integrated circuits including an upper pin holder and a lower pin holder coupled to the upper pin holder. A pin arrangement space is defined between the upper pin holder and the lower pin holder. A conductive film is disposed between the upper pin holder and the lower pin holder. A plurality of probe pins penetrates through the upper pin holder, the conductor film and the lower pin holder, and extends outwardly from a bottom surface of the lower pin holder. At least one ground pin is included. The at least one ground pin includes a head terminal penetrating through the upper pin holder and a tip terminal landed on the conductive film to provide ground voltage to the conductive film during testing. The tip terminal of the at least one ground pin does not penetrate through the conductive film and the lower pin holder.

According to some embodiments, the conductive film is disposed directly on an interior surface of the lower pin holder.

According to some embodiments, the conductive film is a metal film.

According to some embodiments, the plurality of probe pins includes cobra pins or MEMS pins.

According to some embodiments, the probe pins include a pre-bent signal pin and a pre-bent ground pin disposed in close proximity to the pre-bent signal pin.

According to some embodiments, the lower pin holder comprises an annular half-etched trench surrounding the pre-bent signal pin, and the conductive film extends into the annular half-etched trench.

According to some embodiments, the conductive film is part of a multi-layered substrate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 is a schematic, sectional view showing an exemplary system for probing semiconductor wafers in accordance with one embodiment of the invention;

FIG. 2 is a partial layout diagram showing exemplary probe pin arrangement of a probe head when a forbidden region is established;

FIG. 3 is a schematic, sectional diagram showing an exemplary probe head according to another embodiment of the invention;

FIG. 4 is a schematic, sectional diagram showing an exemplary probe head according to still another embodiment of the invention; and

FIG. 5 is a schematic, sectional view showing an exemplary system for probing semiconductor wafers in accordance with yet another embodiment of the invention.

### DETAILED DESCRIPTION

In the following detailed description of embodiments of the invention, reference is made to the accompanying drawings, which form a part hereof, and in which is shown by way of illustration specific preferred embodiments in which the disclosure may be practiced.

These embodiments are described in sufficient detail to enable those skilled in the art to practice them, and it is to be understood that other embodiments may be utilized and that mechanical, structural, and procedural changes may be made without departing from the spirit and scope of the present disclosure. The following detailed description is, therefore, not to be taken in a limiting sense, and the scope of embodiments of the present invention is defined only by the appended claims.

It will be understood that, although the terms first, second, third, primary, secondary, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first or primary element, component, region, layer or section discussed below could be termed a second or secondary element, component, region, layer or section without departing from the teachings of the present inventive concept.

Spatially relative terms, such as “beneath”, “below”, “lower”, “under”, “above,” “upper,” “over” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” or “over” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items, and may be abbreviated as “/”.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present. In contrast, when an element is referred to as being “directly on,” “directly connected to”, “directly coupled to”, or “immediately adjacent to” another element or layer, there are no intervening elements or layers present.

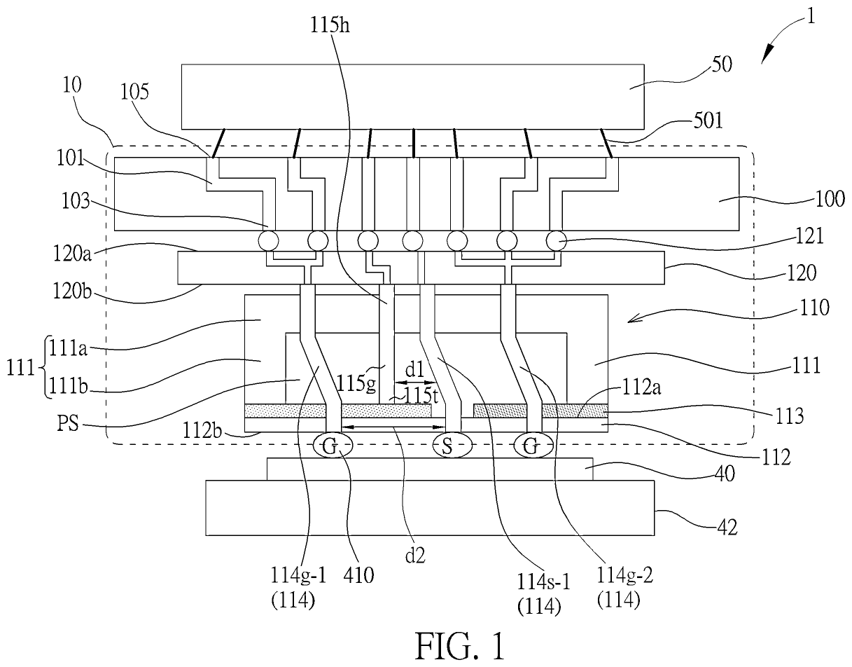

Please refer to FIG. 1. FIG. 1 is a schematic, sectional view showing an exemplary system for probing semiconductor wafers in accordance with one embodiment of the invention. As shown in FIG. 1, a probing system 1 includes a probe card assembly 10 that is used to for making electrical contacts to conductors 410 on a device under test (DUT) 40 such as a wafer or integrated circuits formed on a semiconductor wafer. According to some embodiments, the conductors 410 may include, but not limited to, bonding pads, bumps, solder balls, conductive traces, or the like. Bonding pads, bumps, and solder balls are for routing electrical signals, power or ground voltages among components and/or integrated circuits formed on or in the DUT 40. According to some embodiments, for example, the DUT 40 may be supported by a chuck 42.

The DUT 40 may include electronic components formed in and/or on a semiconductor substrate. Examples of such electronic components include, but are not limited to, transistors, complementary metal oxide semiconductor (CMOS) transistors, bipolar junction transistors (BJT), high voltage transistors, high frequency transistors, p-channel and/or n-channel field effect transistors, resistors, diodes, capacitors, inductors, fuses; and other suitable elements. The electronic components are interconnected to form integrated circuit devices, such as a logic device, memory device, RF device, input/output (I/O) device, system-on-chip (SoC) device, combinations thereof, and other suitable types of devices.

According to some embodiments, for example, the probe card assembly 10 may be a high-frequency, radio-frequency (RF) probe card assembly and may be electrically connected to a tester 50 through conductive path 501. The tester 50 transmits test signals to the DUT 40 or receives output signals from the DUT 40, thereby achieving effect of measuring electrical characteristics of the DUT 40. The tester 50 may also be referred to as automatic test equipment (ATE). Prior to wafer dicing wherein the individual integrated circuit dice are separated from the semiconductor wafer, electrical performance and reliability tests are performed. The resulting electrical signals generated from each DUT are captured and analyzed by the ATE having test circuitry to determine if the DUT is defective.

According to an embodiment of the invention, the probe card assembly 10 includes a probe card circuit board 100 composed of a printed circuit board, a probe head 110 disposed under the probe card circuit board 100, and an interposing substrate 120 disposed between the probe card circuit board 100 and the probe head 110. The interposing substrate 120 is interposed between the probe card circuit board 100 and the probe head 110 to further facilitate signal routing from the probe card circuit board 100 to the probe head 110.

According to an embodiment of the invention, the probe card circuit board 100 includes conductive traces 101, which are connected in a test circuit relationship to the tester 50. An array of lands 103 such as copper pads may be provided on a lower surface of the probe card circuit board 100 for connection with the interposing substrate 120. The conductive traces 101 may lead to other contacts 105 such as pogo pads on the upper surface of the probe card circuit board 100 to which the tester 50 are connected to implement a prescribed test.

According to an embodiment of the invention, the interposing substrate 120 has a first interface 120a coupled to the probe card circuit board 100 and a second interface 120b coupled to the probe head 110. The interposing substrate 120 may comprise a multi-layer ceramic substrate, a multi-layer organic substrate, or a semiconductor interposer substrate, but is not limited thereto. The interposing substrate 120 is configured to route electrical signals between the probe card circuit board 100 and the probe head 110. According to an embodiment of the invention, for example, the first interface 120a of the interposing substrate 120 may comprise a plurality of bump contacts 121, which may be formed into an array. The bump contacts 121 are reflowed to form an electrical and mechanical bond to corresponding lands 103 on the lower surface of the probe card circuit board 100.

According to an embodiment of the invention, the probe head 110 includes an upper pin holder 111 and a lower pin holder 112 coupled to the upper pin holder 111. A pin arrangement space PS is defined between the upper pin holder 111 and the lower pin holder 112. A conductive film 113 is disposed between the upper pin holder 111 and the lower pin holder 112. A number of probe pins 114 penetrate through the upper pin holder 111, the conductive film 113, and the lower pin holder 112, and extends outwardly from a bottom surface 112b of the lower pin holder 112. According to an embodiment of the invention, the lower pin holder 112 may have a multi-layer structure. According to an embodiment of the invention, the upper pin holder 111 may comprise a horizontal top portion 111a and a vertical wall portion 111b. The probe pins 114 may comprise resilient structures configured to make contact with the contact pads of the interposing substrate 120.

According to an embodiment of the invention, the probe pins 114 may be arranged in an array and may be of any configuration suitable for probing semiconductor wafers or dies. According to an embodiment of the invention, for example, the probe pins 114 are resilient pins enabling the probe pins 114 to move toward and away from the interposing substrate 120, and to be connected to and disconnected from the interposing substrate 120. When the probe card assembly 10 is electrically contacted with the conductors 410 of the DUT 40, elastic deformation of the probe pins 114 can absorb reversed stress during a test. That is, the pin arrangement space may serve as an elastic deformation space of the probe pins 114.

According to an embodiment of the invention, the probe pins 114 may be cobra pins, MEMS pins or other types of probe pins, and are not limited thereto. For example, the probe pins 114 may be cobra pins including a first pre-bent signal pin 114s-1 and a first pre-bent ground pin 114g-1 that is disposed in close proximity to the first pre-bent signal pin 114s-1. A second pre-bent ground pin 114g-2 is disposed in close proximity to the first pre-bent signal pin 114s-1. The first pre-bent signal pin 114g-1 is disposed between the first pre-bent ground pin 114g-1 and the second pre-bent ground pin 114g-2, thereby forming a GSG (ground-signal-ground) pin configuration. According to an embodiment of the invention, the probe pins 114 are bent at a selected angle within the pin arrangement space PS. According to an embodiment of the invention, during testing, the tip terminals of the probe pins 114 that extend outwardly from the bottom surface 112b of the lower pin holder 112 may align and contact with the corresponding conductors 410 of the DUT 40. The head terminals of the probe pins 114 are electrically connected to the second interface 120b of the interposing substrate 120. The first pre-bent signal pin 114s-1 is not in direct contact with the conductive film 113 to avoid shorting.

According to an embodiment of the invention, the conductive film 113 is disposed directly on an interior surface 112a of the lower pin holder 112. According to an embodiment of the invention, the conductive film 113 may comprise a metal film such as a copper film or a copper foil, but is not limited thereto.

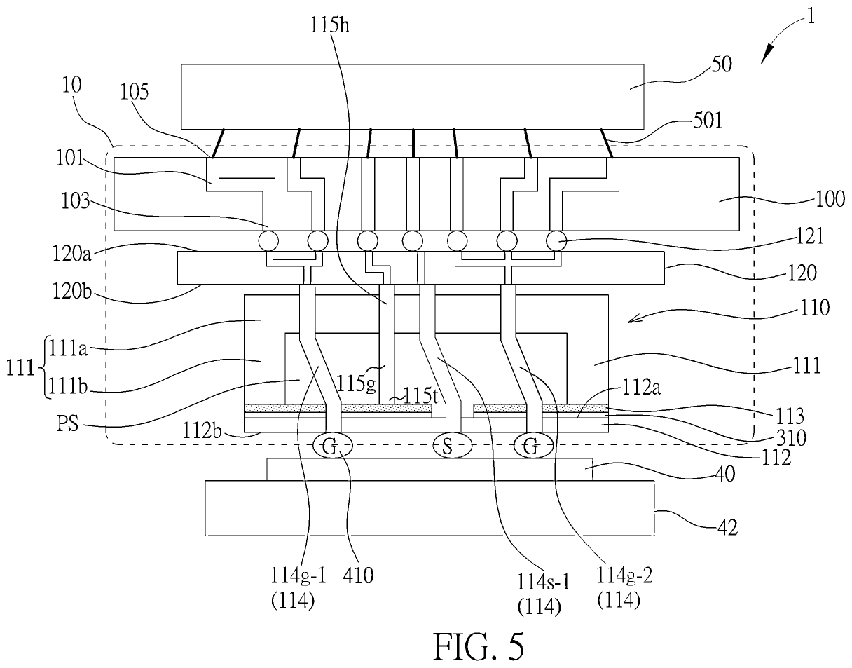

According to another embodiment of the present invention, as shown in FIG. 5, the conductive film 113 may be a part of a multi-layered substrate 310, e.g., a metal layer within a multi-layered printed circuit substrate. In such embodiments, the multi-layered substrate 310 may be disposed on the interior surface 112a of the lower pin holder 112 and allows the probe pins 114 penetrating therethrough.

According to an embodiment of the invention, the probe head 110 further includes at least one ground pin 115g extending between the upper pin holder 111 and the conductive film 113. According to an embodiment of the invention, the at least one ground pin 115g is a straight pin. In some embodiments, the at least one ground pin 115g may be a pre-bent pin.

According to an embodiment of the invention, the at least one ground pin 115g may comprise a head terminal 115h penetrating through the upper pin holder 111 and a tip terminal 115t landed on the conductive film 113 to provide ground voltage to the conductive film 113 during testing. According to an embodiment of the invention, the tip terminal 115t of the at least one ground pin 115g is in direct contact with the conductive film 113. The tip terminal 115t may extend into the conductive film 113 but does not penetrate through the conductive film 113 and the lower pin holder 112. In some embodiments, the tip terminal 115t may be merely in direct contact with a top surface of the conductive film 113 as illustrated in FIG. 1. The conductive film 113 provides a virtual ground plane during testing, which alleviates needle parasitic effects and improves impendence matching. Further, the introduction of the ground pin 115g and the conductive film 113 can reduce inductance effect in the test path for high-power products, thereby enhancing power delivery network (PDN) IR drop performance. Further, the introduction of the ground pin 115g and the conductive film 113 can reduce needle parasitic effects and improve the electronic response at high RF frequencies during testing.

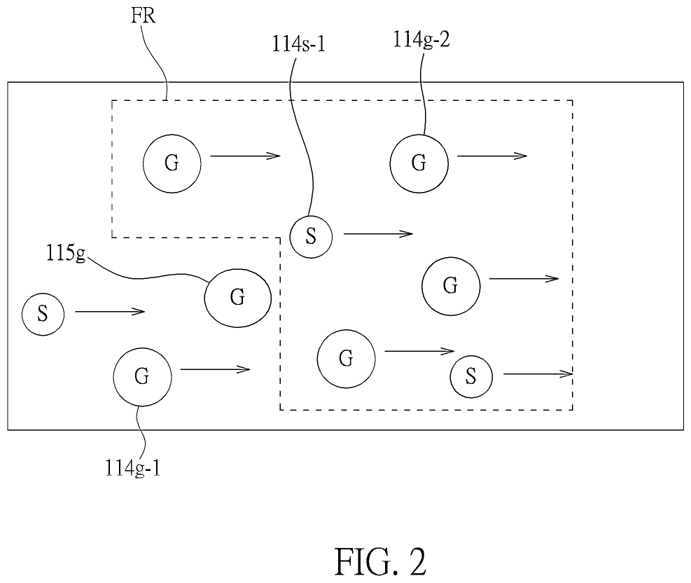

According to an embodiment of the invention, for example, a distance d1 between the at least one ground pin 115g and the first pre-bent signal pin 114s-1 is smaller than a distance d2 between the first pre-bent ground pin 114g-1 and the first pre-bent signal pin 114s-1. According to an embodiment of the invention, preferably, a distance between the at least one ground pin 115g and an adjacent probe pin 114 is greater than or equal to 50 micrometers, for example, 100 micrometers. Based on this rule (minimum distance rule), a forbidden region may be established for the pin assembly. FIG. 2 is a partial layout diagram showing exemplary probe pin arrangement of a probe head when a forbidden region is established, wherein like layers, elements or areas are designated by like numeral numbers or labels. In FIG. 2, the arrows indicate the direction of pin bending direction. As shown in FIG. 2, the at least one ground pin 115g is disposed outside the forbidden region FR because the disposal of an extra ground pin in the forbidden region FR would violate the minimum distance rule.

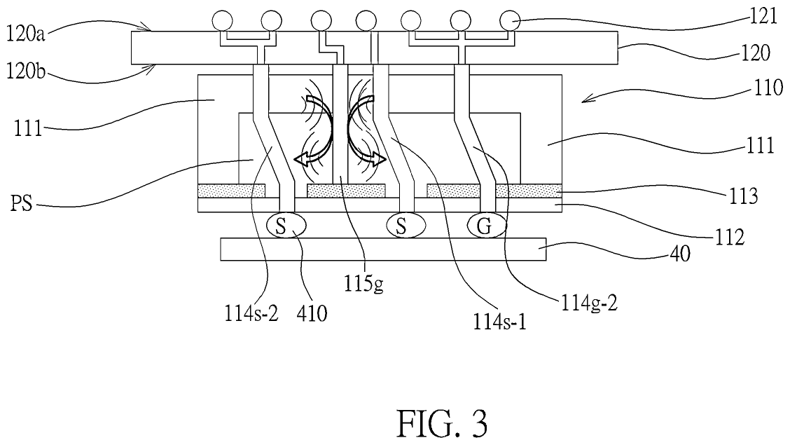

FIG. 3 is a schematic, sectional diagram showing an exemplary probe head according to another embodiment of the invention, wherein like layers, elements or areas are designated by like numeral numbers or labels. For the sake of simplicity, only the interposing substrate 120, the probe head 110, and the DUT 40 are illustrated.

As shown in FIG. 3, according to an embodiment, the probe head 110 further includes a second pre-bent signal pin 114s-2 disposed in close proximity to the first pre-bent signal pin 114s-1. The coupling effect between the closely arranged first pre-bent signal pin 114s-1 and second pre-bent signal pin 114s-2 is problematic. The address this issue, the at least one ground pin 115g may be disposed between the first pre-bent signal pin 114s-1 and the second pre-bent signal pin 114s-2 to enhance signal isolation between signal paths.

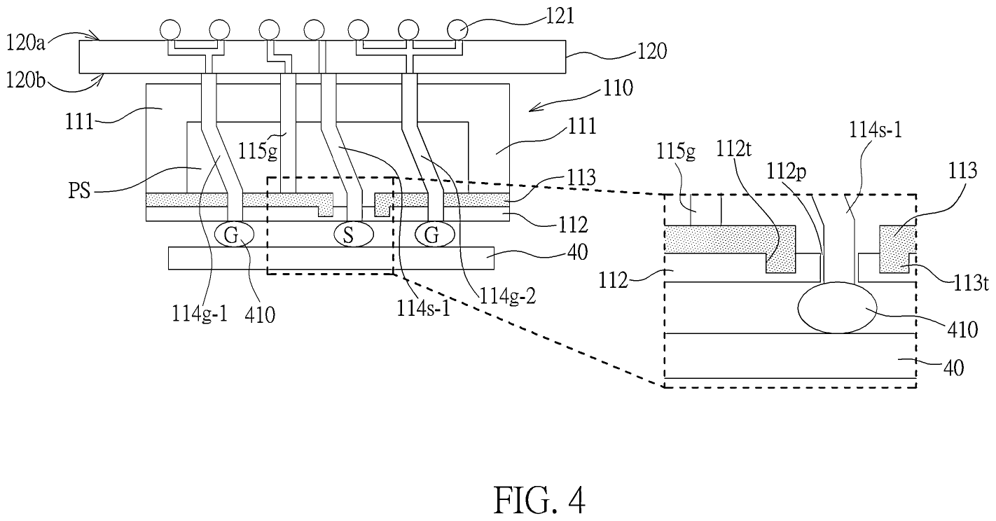

FIG. 4 is a schematic, sectional diagram showing an exemplary probe head according to still another embodiment of the invention, wherein like layers, elements or areas are designated by like numeral numbers or labels. For the sake of simplicity, only the interposing substrate 120, the probe head 110, and the DUT 40 are illustrated.

As shown in FIG. 4, likewise, the probe pins 114 may be cobra pins including a first pre-bent signal pin 114s-1 and a first pre-bent ground pin 114g-1 that is disposed in close proximity to the first pre-bent signal pin 114s-1. A second pre-bent ground pin 114g-2 is disposed in close proximity to the first pre-bent signal pin 114s-1. The first pre-bent signal pin 114g-1 is disposed between the first pre-bent ground pin 114g-1 and the second pre-bent ground pin 114g-2, thereby forming a GSG pin configuration within the pin arrangement space PS and GSG bump or pad arrangement on the DUT 40. According to an embodiment of the invention, the probe pins 114 are bent at a selected angle within the pin arrangement space PS.

According to an embodiment of the invention, during testing, the tip terminals of the probe pins 114 that extend outwardly from the bottom surface 112b of the lower pin holder 112 may align and contact with the corresponding conductors 410 of the DUT 40. The head terminals of the probe pins 114 are electrically connected to the second interface 120b of the interposing substrate 120. The first pre-bent signal pin 114s-1 is not in direct contact with the conductive film 113 to avoid shorting.

According to an embodiment of the invention, to reduce the discontinuity effect and improve the high-frequency response characteristics, an annular half-etched trench (or blind hole) 112t is provided to surround the first pre-bent signal pin 114s-1. The conductive film 113 extends into the annular half-etched trench 112t to form shielding structure 113t around the portion of the first pre-bent signal pin 114s-1 that passes through the through hole 112p of the lower pin holder 112. According to an embodiment of the invention, the annular half-etched trench 112t may be completely filled with the conductive film 113.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An apparatus for testing integrated circuits, comprising:
a probe card circuit board;
a probe head, disposed under the probe card circuit board, the probe head comprising an upper pin holder, a lower pin holder coupled to the upper pin holder thereby defining a pin arrangement space between the upper pin holder and the lower pin holder, a conductive film disposed between the upper pin holder and the lower pin holder, and a plurality of probe pins penetrating through the upper pin holder, the conductor film and the lower pin holder, and extending outwardly from a bottom surface of the lower pin holder; and
an interposing substrate, disposed between the probe card circuit board and the probe head, the interposing substrate comprising a first interface coupled to the probe card circuit board and a second interface coupled to the probe head.

2. The apparatus for testing integrated circuits according to claim 1, wherein the conductive film is disposed directly on an interior surface of the lower pin holder.

3. The apparatus for testing integrated circuits according to claim 1, wherein the conductive film is a metal film.

4. The apparatus for testing integrated circuits according to claim 1, wherein the plurality of probe pins comprises cobra pins or MEMS pins.

5. The apparatus for testing integrated circuits according to claim 1, wherein the probe pins comprise a first pre-bent signal pin and a first pre-bent ground pin disposed in close proximity to the first pre-bent signal pin.

6. The apparatus for testing integrated circuits according to claim 5, wherein the probe head further comprises a second pre-bent ground pin disposed in close proximity to the first pre-bent signal pin, wherein the first pre-bent signal pin is disposed between the first pre-bent ground pin and the second pre-bent ground pin, thereby forming a GSG pin configuration.

7. The apparatus for testing integrated circuits according to claim 5, wherein the probe head further comprises at least one ground pin, wherein the at least one ground pin comprises a head terminal penetrating through the upper pin holder and a tip terminal landed on the conductive film to provide ground voltage to the conductive film during testing.

8. The apparatus for testing integrated circuits according to claim 7, wherein the tip terminal of the at least one ground pin is in direct contact with the conductive film.

9. The apparatus for testing integrated circuits according to claim 7, wherein a distance between the at least one ground pin and the first pre-bent signal pin is smaller than a distance between the first pre-bent ground pin and the first pre-bent signal pin.

10. The apparatus for testing integrated circuits according to claim 7, wherein the probe head further comprises a second pre-bent signal pin disposed in close proximity to the first pre-bent signal pin, wherein the at least one ground pin is disposed between the first pre-bent signal pin and the second pre-bent signal pin.

11. The apparatus for testing integrated circuits according to claim 1, wherein the conductive film is part of a multi-layered substrate.

12. A probe head of a probe card assembly for testing integrated circuits, comprising:
an upper pin holder;
a lower pin holder coupled to the upper pin holder thereby defining a pin arrangement space between the upper pin holder and the lower pin holder;
a conductive film disposed between the upper pin holder and the lower pin holder; and
a plurality of probe pins penetrating through the upper pin holder, the conductor film and the lower pin holder, and extending outwardly from a bottom surface of the lower pin holder.

13. The probe head of a probe card assembly for testing integrated circuits according to claim 12, wherein the conductive film is disposed on an interior surface of the lower pin holder.

14. The probe head of a probe card assembly for testing integrated circuits according to claim 12, wherein the conductive film is a metal film.

15. The probe head of a probe card assembly for testing integrated circuits according to claim 12, wherein the conductive film is in direct contact with the lower pin holder.

16. The probe head of a probe card assembly for testing integrated circuits according to claim 12, wherein the plurality of probe pins comprises cobra pins or MEMS pins.

17. The probe head of a probe card assembly for testing integrated circuits according to claim 12, wherein the probe pins comprise a first pre-bent signal pin and a first pre-bent ground pin disposed in close proximity to the first pre-bent signal pin.

18. The probe head of a probe card assembly for testing integrated circuits according to claim 17 further comprising:
a second pre-bent ground pin disposed in close proximity to the first pre-bent signal pin, wherein the first pre-bent signal pin is disposed between the first pre-bent ground pin and the second pre-bent ground pin, thereby forming a GSG pin configuration.

19. The probe head of a probe card assembly for testing integrated circuits according to claim 17 further comprising:
at least one ground pin, wherein the at least one ground pin comprises a head terminal penetrating through the upper pin holder and a tip terminal landed on the conductive film to provide ground voltage to the conductive film during testing.

20. The probe head of a probe card assembly for testing integrated circuits according to claim 19, wherein the tip terminal of the at least one ground pin is in direct contact with the conductive film.

21. The probe head of a probe card assembly for testing integrated circuits according to claim 19, wherein a distance between the at least one ground pin and the first pre-bent signal pin is smaller than a distance between the first pre-bent ground pin and the first pre-bent signal pin.

22. The probe head of a probe card assembly for testing integrated circuits according to claim 19, wherein the probe head further comprises a second pre-bent signal pin disposed in close proximity to the first pre-bent signal pin, wherein the at least one ground pin is disposed between the first pre-bent signal pin and the second pre-bent signal pin.

23. The probe head of a probe card assembly for testing integrated circuits according to claim 12, wherein the conductive film is part of a multi-layered substrate.

24. A probe head of a probe card assembly for testing integrated circuits, comprising:
an upper pin holder;
a lower pin holder coupled to the upper pin holder thereby defining a pin arrangement space between the upper pin holder and the lower pin holder;
a conductive film disposed between the upper pin holder and the lower pin holder;
a plurality of probe pins penetrating through the upper pin holder, the conductor film and the lower pin holder, and extending outwardly from a bottom surface of the lower pin holder; and
at least one ground pin comprising a head terminal penetrating through the upper pin holder and a tip terminal landed on the conductive film to provide ground voltage to the conductive film during testing, wherein the tip terminal of the at least one ground pin does not penetrate through the conductive film and the lower pin holder.

25. The probe head of a probe card assembly for testing integrated circuits according to claim 24, wherein the conductive film is disposed directly on an interior surface of the lower pin holder.

26. The probe head of a probe card assembly for testing integrated circuits according to claim 24, wherein the conductive film is a metal film.

27. The probe head of a probe card assembly for testing integrated circuits according to claim 24, wherein the plurality of probe pins comprises cobra pins or MEMS pins.

28. The probe head of a probe card assembly for testing integrated circuits according to claim 24, wherein the probe pins comprise a pre-bent signal pin and a pre-bent ground pin disposed in close proximity to the pre-bent signal pin.

29. The probe head of a probe card assembly for testing integrated circuits according to claim 28, wherein the lower pin holder comprises an annular half-etched trench surrounding the pre-bent signal pin, and the conductive film extends into the annular half-etched trench.

30. The probe head of a probe card assembly for testing integrated circuits according to claim 24, wherein the conductive film is part of a multi-layered substrate.
